(19) United States
(12) Patent Application Publication
(10) Pub. No.: US 2018/0171501 A1
(43) Pub. Date: Jun. 21, 2018

(54) PLATING APPARATUS, PLATING METHOD AND COMPUTER READABLE RECORDING MEDIUM

(71) Applicant: Ebara Corporation, Tokyo (JP)

(72) Inventors: Yasuyuki Masuda, Tokyo (JP); Masashi Shimoyama, Tokyo (JP); Takashi Kishi, Tokyo (JP)

(21) Appl. No.: 15/832,504

(22) Filed: Dec. 5, 2017

(30) Foreign Application Priority Data
Dec. 19, 2016 (JP) 2016-245651

(51) Int. Cl. C25D 5/02; C25D 17/06; C25D 17/12; C25D 21/04; C25D 21/10; C25D 21/14; H01L 21/288

(52) U.S. Cl. CPC C25D 5/02; C25D 17/06; C25D 17/12; H01L 21/288; C25D 21/10; C25D 21/14; C25D 21/04

(57) ABSTRACT

There is provided a plating apparatus for performing plating treatment on a substrate having a resist pattern. The plating apparatus includes: a pretreatment unit for causing a surface of the substrate to be brought into contact with a pretreatment solution; and a plating bath in which the plating treatment is performed on the substrate having a surface to be treated which is brought into contact with the pretreatment solution. The pretreatment unit includes: a holding table for holding the substrate with the surface to be treated facing upward; a motor for rotating the holding table; a hydrophilizing treatment portion for irradiating ultraviolet rays to the surface to be treated; and a pretreatment solution supply portion for supplying the pretreatment solution to the surface to be treated which is hydrophilized by the hydrophilizing treatment portion.

### CROSS-REFERENCE TO RELATED APPLICATION

This application is based upon and claims benefit of priority from Japanese Patent Application No. 2016-245651 filed on Dec. 19, 2016, the entire contents of which are incorporated herein by reference.

### TECHNICAL FIELD

The present invention relates to a plating apparatus, a plating method, and a computer readable recording medium.

### BACKGROUND ART

Conventionally, a technique is used where wirings are formed in minute wiring grooves, holes or resist openings formed on a surface of a semiconductor wafer or the like, and bumps (protruding electrodes), which are electrically connected with electrodes or the like of a package, are formed on the surface of the semiconductor wafer or the like. As a method of forming such wirings and bumps, a method such as an electrolytic plating method, a vapor deposition method, a printing method or a ball bump method is used, for example. However, with the increase in number of I/Os of a semiconductor chip and fine pitch arrangement of wirings and bumps, the use of an electrolytic plating method has increased where wirings and bumps can be further miniaturized while performance of the wirings and the bumps is relatively stabilized.

In forming bumps or wirings using an electrolytic plating method at predetermined positions of a substrate on which wirings are formed, a technique of using a resist as a mask is widely used. To be more specific, a seed layer as a power supply layer is formed on a front surface of a substrate, and a resist having a height of 20 to 120 μm, for example, is applied by coating to a surface of the seed layer. Thereafter, opening portions having a diameter of approximately 5 to 200 μm, for example, are formed at predetermined positions of the resist layer so that a resist pattern is formed.

In electrolytic plating where bumps are formed in the inside of the resist pattern (resist openings), an anode and a substrate are immersed into a plating solution, and a voltage is applied between the anode and the substrate. To facilitate intrusion of the plating solution into the resist openings or through holes formed on a front surface of the substrate, pre-wetting treatment is performed where air present in the resist openings or the through holes is replaced with a pre-wetting liquid (pretreatment solution). As such pre-wetting treatment, a technique is used where a substrate is immersed into a pre-wetting liquid held in a pre-wetting bath (see Japanese Patent Laid-Open No. 2007-138304 (PTL 1)).

There has been used electrolytic plating where metal is embedded into a wafer where recessed portions referred to as via holes are formed on a surface of an insulating film, and a conductive layer such as a seed layer is formed on the flat surface of the insulating film and a surface of the recessed portions. Also in applying such electrolytic plating to the wafer, the above-mentioned pre-wetting treatment is performed before the electrolytic plating is applied to the wafer.

There has been also used a plating apparatus where a resist surface is hydrophilized by an ashing device before such pre-wetting treatment is performed (see Japanese Patent Laid-Open No. 2005-240108 (PTL 2)).

### CITATION LIST

### Patent Literature

PTL 1: Japanese Patent Laid-Open No. 2007-138304

PTL 2: Japanese Patent Laid-Open No. 2005-240108

### SUMMARY OF INVENTION

### Technical Problem

As described in PTL 1, in conventional pre-wetting treatment, the entire substrate is immersed into a pre-wetting liquid thus requiring a large amount of pre-wetting liquid. Further, each time pre-wetting treatment is performed on one substrate, it is necessary to replace a pre-wetting liquid in the pre-wetting bath. It takes a long time to discharge the pre-wetting liquid from the pre-wetting bath and to store a new pre-wetting liquid in the pre-wetting bath. Accordingly, in the conventional pre-wetting treatment, there is a demand for reducing an amount of pre-wetting liquid used and for shortening a time required for performing the pre-wetting treatment.

In the conventional plating method, it is not always the case that plating treatment is performed immediately after ashing treatment is performed on a resist in a wiring forming step. That is, a length of time before plating is applied to a substrate after ashing treatment is performed in the wiring forming step varies depending on a process condition. With the lapse of time after ashing treatment is performed in the wiring forming step, organic substances adhere to a resist surface and/or a seed layer of a substrate so that characteristics of the resist surface and/or the seed layer change from being hydrophilic to hydrophobic.

When plating is applied to a substrate after a lapse of long time from the ashing treatment, a front surface of the substrate is hydrophobized so that a pre-wetting liquid may not enter resist openings on the substrate or air bubbles may adsorb to a surface to be plated of the substrate and the air bubbles cannot be easily removed. Accordingly, a defective plated substrate may be produced.

In the plating apparatus described in PTL 2, a resist surface is hydrophilized by the ashing device before pre-wetting treatment is performed. However, in the plating apparatus, the ashing device and a pre-wetting bath are disposed separately, and ashing treatment is performed on a substrate before the substrate is held by a substrate holder, and pre-wetting treatment is performed on the substrate held by the substrate holder. Accordingly, depending on the state of a substrate on which plating treatment is performed, the substrate cannot be promptly transferred so that there may be a case where pre-wetting treatment cannot be performed immediately after ashing treatment is performed. For this reason, a time from the ashing treatment to the pre-wetting treatment varies between substrates so that there is a possibility of variations in the degree of hydrophilicity.

The present invention has been made in view of the above-mentioned problems, and it is an object of the present invention to enhance hydrophilicity of a resist surface and/or a seed layer of a substrate, and to suppress variations in the degree of hydrophilicity between substrates.

### Solution to Problem

According to one aspect of the present invention, there is provided a plating apparatus for performing plating treatment on a substrate. The plating apparatus includes: a pretreatment unit configured to cause a surface of the substrate to be brought into contact with a pretreatment solution; and a plating bath in which the plating treatment is performed on the substrate having the surface which is brought into contact with the pretreatment solution. The pretreatment unit includes: a holding table configured to hold the substrate with the surface of the substrate facing upward; a motor configured to rotate the holding table; a hydrophilizing treatment portion configured to irradiate ultraviolet rays to the surface; and a pretreatment solution supply portion configured to supply the pretreatment solution to the surface which is hydrophilized by the hydrophilizing treatment portion.

According to another aspect of the present invention, there is provided a plating method. The plating method includes: a step of placing a substrate on a holding table; a step of performing hydrophilizing treatment by irradiating ultraviolet rays to a surface of the substrate placed on the holding table; a step of supplying a pretreatment solution to the surface of the substrate on which the hydrophilizing treatment is performed; a step of rotating the holding table holding the substrate having the surface supplied with the pretreatment solution; and a plating step of performing plating treatment on the substrate having the surface supplied with the pretreatment solution.

### BRIEF DESCRIPTION OF DRAWINGS

FIG. 1 is an overall layout diagram showing a plating apparatus according to an embodiment;

FIG. 2 is a perspective view of a substrate holder used in the plating apparatus;

FIG. 3 is a cross-sectional view showing an electrical contact of the substrate holder;

FIG. 4 is a flowchart showing treatment performed on a substrate in the plating apparatus;

FIG. 5A is a schematic side cross-sectional view of a pretreatment unit according to the embodiment;

FIG. 5B is a schematic top plan view of the pretreatment unit according to the embodiment;

FIG. 6 is a flowchart showing pretreatment performed on a substrate in the pretreatment unit;

FIG. 7A is a view showing the pretreatment unit irradiating ultraviolet rays to the substrate;

FIG. 7B is a view showing the pretreatment unit supplying a pretreatment solution to the substrate;

FIG. 7C is a view showing the pretreatment unit blowing a dry gas onto the substrate; and

FIG. 8 is a schematic top plan view of a pretreatment unit according to another embodiment.

### DESCRIPTION OF EMBODIMENTS

Hereinafter, plating apparatuses according to embodiments of the present invention are described with reference to drawings. In drawings described hereinafter, identical or corresponding constitutional elements are given the same symbols, and repeated description is omitted. An electroplating apparatus is described hereinafter as one example of the plating apparatus. However, the plating apparatus is not limited to the electroplating apparatus, and an electroless plating apparatus may be adopted as the plating apparatus of the present invention.

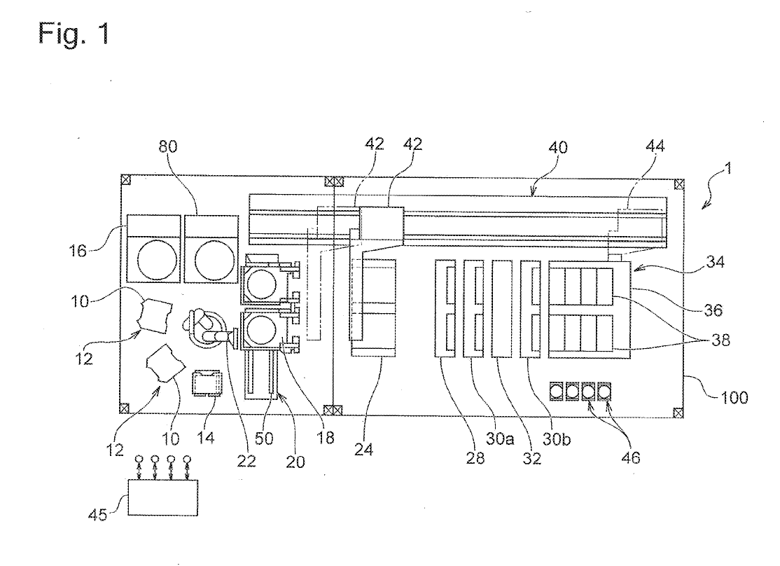

FIG. 1 is an overall layout diagram showing the plating apparatus according to this embodiment. As shown in FIG. 1, the entire plating apparatus 1 is surrounded by a frame 100, and a space surrounded by the frame 100 is defined as the plating apparatus 1. The plating apparatus 1 includes: two cassette tables 12 each mounting a cassette 10 which stores substrates such as semiconductor wafers; an aligner 14 for aligning the position of an orientation flat or a notch formed on a substrate in the predetermined direction; a substrate attaching and detaching portion 20 for attaching and detaching a substrate to and from a substrate holder 60 placed on the substrate attaching and detaching portion 20; and a cleaning device (spin rinse dryer) 16 for cleaning the substrate, on which plating treatment is performed, by supplying a cleaning solution (pure water) for cleaning a front surface of the substrate while rotating the substrate and, thereafter, drying the front surface of the substrate by rotating the substrate at a high speed. In addition to the above, the plating apparatus 1 also includes a pretreatment unit 80 for performing pretreatment on the substrate. As described later, the pretreatment unit 80 is configured to modify a surface to be treated of the substrate and, thereafter, to perform pre-wetting treatment on the substrate. A substrate transferring device 22, which is a transfer robot, for example, is disposed at substantially the center of these units, and the substrate transferring device 22 transfers a substrate between these units. The plating apparatus 1 may only include either one of the pretreatment unit 80 or the cleaning device 16. In such a case, either one of the pretreatment unit 80 or the cleaning device 16 is configured to perform both pretreatment and cleaning and drying.

The substrate attaching and detaching portion 20 includes a flat-plate shaped placement plate which is slidable in the horizontal direction along rails 50. In a state where two substrate holders 60 are placed on the placement plate in parallel in a horizontal state, the substrate transferring device 22 transfers and receives a substrate to and from one substrate holder 60. Thereafter, the substrate transferring device 22 makes the placement plate slide in the horizontal direction and, then, transfers and receives a substrate to and from the other substrate holder 60.

The plating apparatus 1 also includes: a stocker 24; a presoaking bath 28; a first cleaning bath 30a; a blow bath 32; a second cleaning bath 30b; and a plating bath 34. The substrate holders 60 are stored and temporarily placed in the stocker 24. An oxide film on a surface of a conductive layer, such as a seed layer formed on the front surface of the substrate, is removed by etching in the presoaking bath 28. The substrate, which is subjected to pre-soaking, is cleaned with a cleaning solution (pure water or the like) together with the substrate holder 60 in the first cleaning bath 30a. The cleaned substrate is drained of a solution in the blow bath 32. The plated substrate is cleaned with a cleaning solution together with the substrate holder 60 in the second cleaning bath 30b. The stocker 24, the presoaking bath 28, the first cleaning bath 30a, the blow bath 32, the second cleaning bath 30b and the plating bath 34 are disposed in this order.

The plating bath 34 includes an overflow bath 36 and a plurality of plating units 38 stored in the overflow bath 36. Each plating unit 38 stores substrate holders 60 holding substrates therein so as to immerse the substrates into a plating solution held in the plating unit 38. By applying a voltage between a substrate and an anode in the plating unit 38, plating such as copper plating is applied to a front surface of the substrate. The same plating apparatus 1 can be used also for applying plating such as nickel plating, solder plating, silver plating or gold plating instead of copper plating.

The plating apparatus 1 further includes a substrate holder transporting device 40 for transporting the substrate holder 60. The substrate holder transporting device 40 is of a linear motor type, for example. The substrate holder transporting device 40 is positioned on the side facing the substrate attaching and detaching portion 20 and the above-mentioned respective baths. The substrate holder transporting device 40 includes: a first transporter 42 for transporting a substrate between the substrate attaching and detaching portion 20 and the stocker 24; and a second transporter 44 for transporting the substrate between the stocker 24, the presoaking bath 28, the cleaning baths 30a, 30b, the blow bath 32 and the plating bath 34. The substrate holder transporting device 40 may include only either one of the first transporter 42 or the second transporter 44.

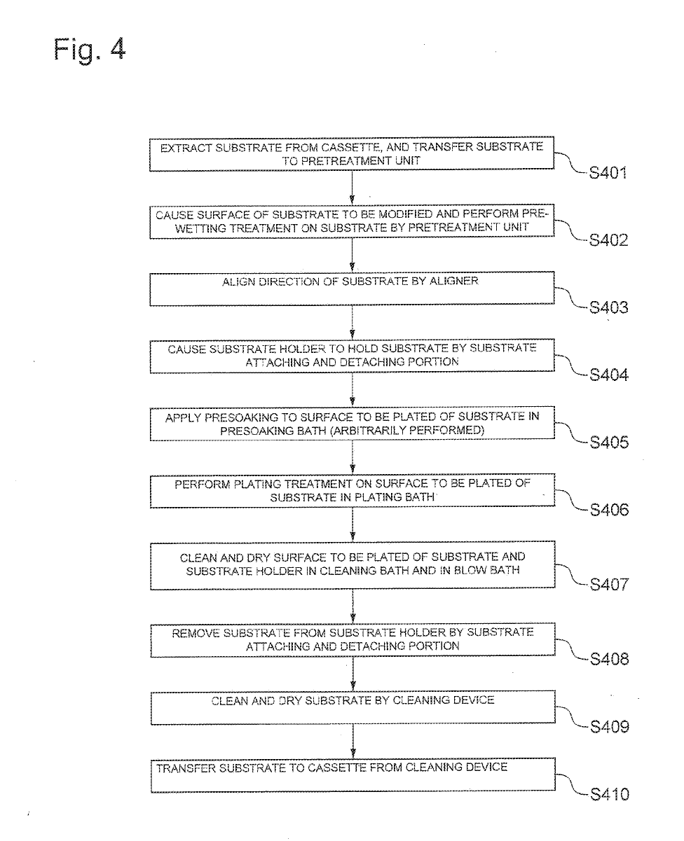

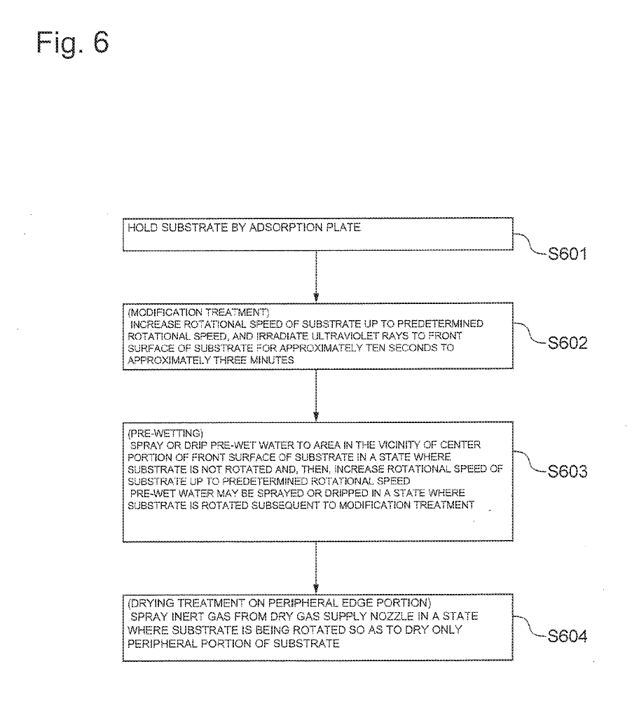

The plating apparatus 1 includes a control part 45 configured to control the operation of the respective parts of the above-mentioned plating apparatus 1. The control part 45 includes, for example, a computer readable recording medium storing a predetermined program for making the plating apparatus 1 perform a process shown in FIG. 4 and FIG. 6 described later, a CPU (Central Processing Unit) (corresponding to one example of a computer) for performing the program in the recording medium and the like. For example, the control part 45 can perform controls such as a transfer control of the substrate transferring device 22, a transport control of the substrate holder transporting device 40, a control of a plating current and a plating time in the plating bath 34 and a control of pretreatment in the pretreatment unit 80 described later. As the recording medium which the control part 45 includes, an arbitrary recording means may be adopted including a magnetic medium such as a flexible disk, a hard disk drive or a memory storage, an optical medium such as a CD or a DVD, or a magneto-optical medium such as an MO or an MD.

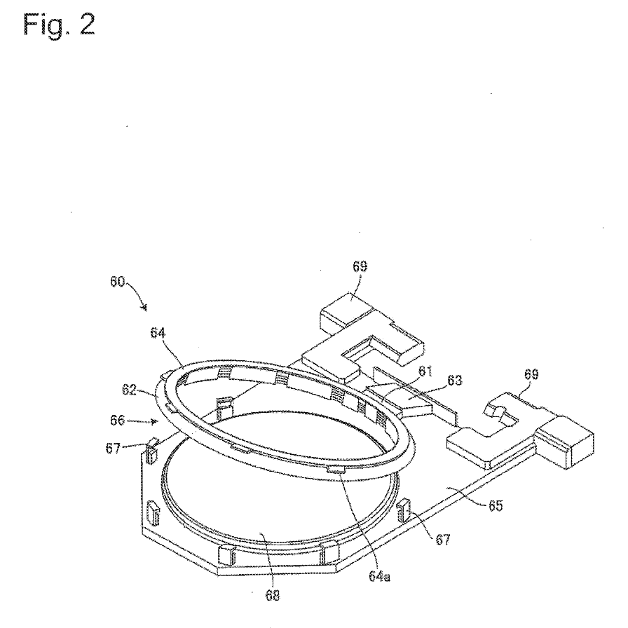

FIG. 2 is a perspective view of the substrate holder 60 used in the plating apparatus shown in FIG. 1. As shown in FIG. 2, the substrate holder 60 includes, for example, a first holding member 65 made of vinyl chloride and having a rectangular-flat-plate shape, and a second holding member 66 openably mounted on the first holding member 65 by way of a hinge 63. A holding surface 68 for holding a substrate is formed at substantially the center portion of the first holding member 65 of the substrate holder 60. Inverted L-shaped clampers 67 are equidistantly formed on the first holding member 65 outside the holding surface 68 along a periphery of the holding surface 68, and each clamper 67 includes a projecting portion which projects inwardly.

A pair of hands 69 having an approximately T shape are continuously connected to an edge portion of the first holding member 65 of the substrate holder 60, and the hands 69 function as support portions when the substrate holder 60 is transported or is supported in a suspended manner. The hands 69 are hooked on an upper surface of a peripheral wall of the stocker 24 in the stocker 24 shown in FIG. 1 so that the substrate holder 60 is supported in a vertically suspended manner. Further, the hands 69 of the substrate holder 60, which are supported in a suspended manner, are grabbed by the first transporter 42 or the second transporter 44 so as to transport the substrate holder 60. Also in the presoaking bath 28, the cleaning baths 30a, 30b, the blow bath 32 and the plating bath 34, the substrate holder 60 is supported in a suspended manner on a peripheral wall of each bath by way of the hands 69.

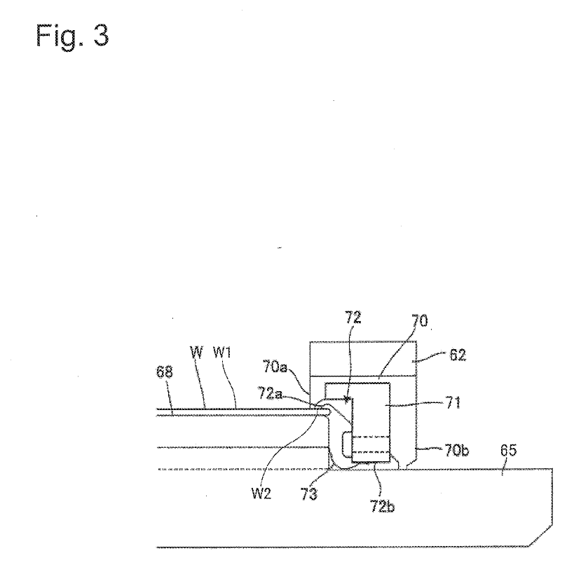

The hand 69 is provided with an external contact not shown in the drawing for connecting the substrate holder 60 to a power supply portion disposed outside the substrate holder 60. The external contact is, through a plurality of wirings, electrically connected with a plurality of conductors 73 (see FIG. 3) disposed on an outer periphery of the holding surface 68.

The second holding member 66 includes a proximal portion 61 fixed to the hinge 63, and a ring-shaped seal holder 62 fixed to the proximal portion 61. A pressing ring 64 is rotatably mounted on the seal holder 62 of the second holding member 66, and the pressing ring 64 presses and fixes the seal holder 62 to the first holding member 65. The pressing ring 64 has a plurality of projecting ridge portions 64a projecting outwardly on an outer peripheral portion of the pressing ring 64. A tapered surface is formed on an upper surface of each projecting ridge portion 64a, and a tapered surface is formed on a lower surface of an inwardly projecting portion of each clamper 67. The tapered surface of the projecting ridge portion 64a and the tapered surface of the clamper 67 incline in directions opposite to each other along the rotational direction.

To hold a substrate by the substrate holder 60, firstly, the substrate is placed on the holding surface 68 of the first holding member 65 in a state where the second holding member 66 is opened and, then, the second holding member 66 is closed. Subsequently, the pressing ring 64 is rotated in the clockwise direction so as to make the projecting ridge portions 64a of the pressing ring 64 slide into the inside of (below) the inwardly projecting portions of the clampers 67. With such an operation, by way of the respective tapered surfaces formed on the pressing ring 64 and the clampers 67, the first holding member 65 and the second holding member 66 are fastened and locked with each other so that the substrate is held. A surface to be plated of the substrate being held is exposed to the outside. To release the holding of the substrate, the pressing ring 64 is rotated in the counterclockwise direction in a state where the first holding member 65 and the second holding member 66 are locked with each other. With such an operation, the projecting ridge portions 64a of the pressing ring 64 are removed from the inverted L-shaped clampers 67 so that the holding of the substrate is released.

FIG. 3 is a cross-sectional view showing an electrical contact of the substrate holder 60 shown in FIG. 2. In an example shown in FIG. 3, a substrate W is placed on the holding surface 68 of the first holding member 65. A plurality of (one in the drawing) conductors 73 are disposed between the holding surface 68 and the first holding member 65, and the conductors 73 are connected to a plurality of wirings extending from the external contacts formed on the hands 69 shown in FIG. 2. The plurality of conductors 73 are disposed outside a circumference of the substrate W such that when the substrate W is placed on the holding surface 68 of the first holding member 65, an end portion of each conductor 73 is exposed to a surface of the first holding member 65 with a spring characteristic on the side of the substrate W.

A sealing member 70 is mounted on a surface (a lower surface in the drawing) of the seal holder 62 which opposedly faces the first holding member 65, and the sealing member 70 is brought into pressure contact with an outer peripheral portion of the front surface of the substrate W and with the first holding member 65 when the substrate W is held by the substrate holder 60. The sealing member 70 includes a lip portion 70a which seals the front surface of the substrate W, and a lip portion 70b which seals a surface of the first holding member 65. That is, the sealing member 70 is configured to provide sealing between the peripheral edge portion of the substrate and a surface of the first holding member 65.

A support body 71 is mounted in a space sandwiched between the pair of lip portions 70a, 70b of the sealing member 70. A plurality of electrical contacts 72, to which a power can be supplied from the conductors 73, are disposed on the support body 71 along the circumference of the substrate W in a state where the electrical contacts 72 are fixed to the support body 71 by screws or the like, for example. The electrical contact 72 includes an electrical contact end portion 72a extending toward the inside of the holding surface 68 and a leg portion 72b to which a power can be supplied from the conductors 73.

When the first holding member 65 and the second holding member 66 shown in FIG. 2 are locked with each other, as shown in FIG. 3, the short lip portion 70a disposed on the inner peripheral surface side of the sealing member 70 is pressed to the front surface of the substrate W, and the long lip portion 70b disposed on the outer peripheral surface side of the sealing member 70 is pressed to the surface of the first holding member 65. With such operations, reliable sealing is provided between the lip portion 70a and the lip portion 70b and, at the same time, the substrate W is held by the substrate holder 60.

In a region sealed by the sealing member 70, that is, in a region sandwiched by the pair of lip portions 70a, 70b of the sealing member 70, the conductors 73 are electrically connected with the leg portions 72b of the electrical contacts 72, and the electrical contact end portions 72a are brought into contact with a conductive layer, for example, a seed layer, at a peripheral edge portion of the substrate W. With such a configuration, a power can be supplied to the substrate W through the electrical contacts 72 in a state where the substrate W is held by the substrate holder 60 while being sealed by the sealing member 70.

Next, treatment performed on a substrate in the plating apparatus 1 is described. FIG. 4 is a flowchart showing treatment performed on a substrate in the plating apparatus 1. As shown in FIG. 4, firstly, the substrate transferring device 22 extracts the substrate from the cassette 10, and transfers the substrate to the pretreatment unit 80 (step S401). The pretreatment unit 80 causes a surface to be plated of the substrate to be hydrophilized (modified) and, thereafter, performs pre-wetting treatment on the substrate (step S402). Subsequently, the substrate transferring device 22 extracts the substrate from the pretreatment unit 80, and transfers the substrate to the aligner 14. The aligner 14 aligns the direction of a notch or an orientation flat formed on the substrate (step S403). The substrate whose direction is aligned is transferred to the substrate attaching and detaching portion 20 by the substrate transferring device 22, and is held by the substrate holder 60 (step S404). The substrate held by the substrate holder 60 is transferred to the presoaking bath 28, and an oxide film on a front surface of the substrate is removed (step S405). The substrate, from which the oxide film is removed, is stored in the first cleaning bath 30a where the substrate is cleaned together with the substrate holder 60. The treatment performed in the presoaking bath 28 and the cleaning performed in the first cleaning bath 30a may be omitted.

Subsequently, the substrate is stored in the plating bath 34 where plating is applied to the front surface of the substrate (step S406). The plated substrate is stored in the second cleaning bath 30b where the surface to be plated of the substrate is cleaned together with the substrate holder 60. Thereafter, the substrate and the substrate holder 60 are dried in the blow bath 32 (step S407). The dried substrate is removed from the substrate holder 60 by the substrate attaching and detaching portion 20 (step S408). The substrate removed from the substrate holder 60 is cleaned and dried by the cleaning device 16 (step S409), and is stored in the cassette 10 (step S410).

Next, pretreatment performed on a substrate in the pretreatment unit 80 is described in detail. As described above, in a wiring forming step, a resist pattern is formed in advance on the substrate on which a seed layer is formed. Before the substrate is transferred to the plating apparatus 1 shown in FIG. 1, UV rays or the like are irradiated to the substrate by an ashing device so that a front surface of the substrate is hydrophilized. Thereafter, the substrate W, on which ashing treatment is performed, is transferred to the plating apparatus 1, and is held by the substrate holder 60. At this stage of the operation, organic substances adhere to the front surface of the substrate W with a time lapse from the ashing treatment so that characteristics of a surface to be plated and a resist surface on the front surface of the substrate change from being hydrophilic to hydrophobic. In view of the above, in the plating apparatus 1 according to this embodiment, the substrate W transferred to the plating apparatus 1 is subject to treatment for modifying the front surface of the substrate W (hydrophilizing treatment) immediately before or simultaneously with the pretreatment (pre-wetting treatment). Accordingly, hydrophilicity of the front surface of the substrate W is enhanced and, at the same time, the degree of hydrophilicity for each substrate can be made uniform.

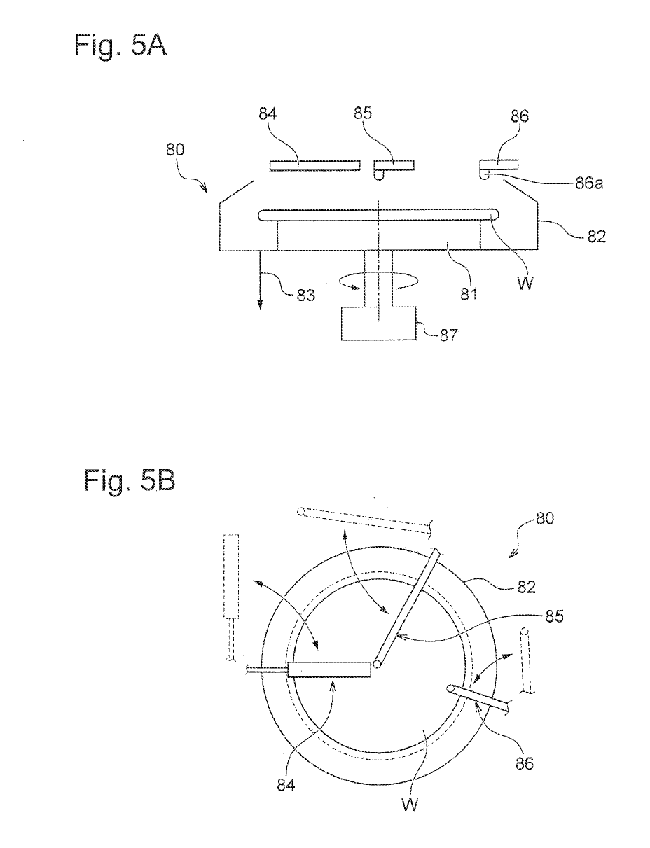

FIG. 5A is a schematic side cross-sectional view of the pretreatment unit 80 according to this embodiment, and FIG. 5B is a schematic top plan view of the pretreatment unit 80 according to this embodiment. As shown in FIG. 5A and FIG. 5B, the pretreatment unit 80 includes: an adsorption plate 81 (corresponding to one example of a holding table); a rotary cup 82; an ultraviolet irradiation device 84 (corresponding to one example of a hydrophilizing treatment portion); a pretreatment solution supply nozzle 85 (corresponding to one example of a pretreatment solution supply portion); a dry gas supply nozzle 86 (corresponding to one example of a gas supply portion); and a motor 87. The adsorption plate 81 is configured to hold the substrate W with the surface to be plated (corresponding to one example of a surface to be treated) of the substrate W facing upward. To be more specific, the adsorption plate 81 includes a vacuum chuck device or an electrostatic chuck device, for example, and the adsorption plate 81 adsorbs a back surface of the substrate W so as to fix the substrate W on the adsorption plate 81. The adsorption plate 81 includes an elevating mechanism not shown in the drawing and, in mounting and dismounting the substrate W on and from the adsorption plate 81, the adsorption plate 81 is moved upward such that an adsorption surface of the adsorption plate 81 is positioned above an upper end portion of the rotary cup 82. The motor 87 is configured to rotate the adsorption plate 81 in the circumferential direction.

The ultraviolet irradiation device 84 is disposed above the adsorption plate 81, and is configured to irradiate ultraviolet rays to the entire front surface (surface-to-be-plated side) of the substrate W. As the ultraviolet irradiation device 84, for example, a device which can irradiate ultraviolet rays such as a low-pressure mercury lamp can be adopted. When the ultraviolet irradiation device 84 is formed of a low-pressure mercury lamp, a main wavelength of ultraviolet rays to be irradiated is 184 nm or 254 nm. The low-pressure mercury lamp may be a straight tube type lamp, a U-shaped lamp, an M-shaped lamp or a rectangular lamp. That is, the low-pressure mercury lamp may have an arbitrary shape which can irradiate ultraviolet rays to a front surface of a substrate. As shown in FIG. 5A and FIG. 5B, it is sufficient for the ultraviolet irradiation device 84 to have a size which can irradiate ultraviolet rays to at least a portion of the substrate W corresponding to a radial size ranging from substantially the center portion to a peripheral edge portion of the substrate W placed on the adsorption plate 81. Accordingly, the ultraviolet irradiation device 84 in this embodiment is disposed so as to extend from substantially the center portion toward the peripheral edge portion of the substrate W placed on the adsorption plate 81. In this embodiment, the substrate W placed on the adsorption plate 81 rotates in the circumferential direction along with the rotation of the adsorption plate 81. Accordingly, with the rotation of the substrate W, ultraviolet rays can be irradiated to the entire front surface (surface-to-be-plated side) of the substrate W. With such a configuration, compared to the case where ultraviolet rays are irradiated to the entire substrate W, a size of the ultraviolet irradiation device 84 can be reduced so that a cost of the ultraviolet irradiation device 84 can be also reduced. The ultraviolet irradiation device 84 may have a size which can irradiate ultraviolet rays to the entire front surface (surface-to-be-plated side) of the substrate W. The pretreatment unit 80 may include a swinging device which causes the ultraviolet irradiation device 84 to swing along the radial direction of the substrate W. In this case, even when the ultraviolet irradiation device 84 has a small size, the substrate W rotates and the ultraviolet irradiation device 84 swings so that ultraviolet rays can be irradiated to the entire front surface (surface-to-be-plated side) of the substrate W.

The pretreatment solution supply nozzle 85 is configured to supply a pretreatment solution to the front surface of the substrate W. As the pretreatment solution, it is possible to adopt any one of or any combination of DIW (De-Ionized Water), dilute sulfuric acid, an aqueous solution containing an additive such as an accelerator, an inhibitor or a leveler which is used in a plating solution, or an aqueous solution containing chloride ions used in the plating solution, for example. The adopted solution does not contain metal ions. For example, when dilute sulfuric acid is used as a pretreatment solution, it is preferable that the dilute sulfuric acid have the same component as dilute sulfuric acid in a plating solution held in the plating bath 34. The pretreatment solution supply nozzle 85 supplies the pretreatment solution to the center of the substrate W. The substrate W rotates along with the rotation of the adsorption plate 81 so that the pretreatment solution supplied to the center of the substrate W spreads uniformly toward the peripheral edge portion of the substrate W due to a centrifugal force. Accordingly, the entire front surface of the substrate W can be brought into contact with the pretreatment solution.

The dry gas supply nozzle 86 is configured to blow an inert gas such as nitrogen or argon onto the peripheral edge portion of the substrate W. An inert gas is blown onto the peripheral edge portion of the substrate W by the dry gas supply nozzle 86 while the substrate W is being rotated. Accordingly, the pretreatment solution adhering to the peripheral edge portion of the substrate W can be removed or dried. As described with reference to FIG. 2 and FIG. 3, the electrical contact end portions 72a of the substrate holder 60 are brought into contact with the peripheral edge portion of the substrate W so that a power is supplied to the seed layer on the front surface of the substrate W. At this stage of the operation, if the peripheral edge portion of the substrate is wetted with the pretreatment solution, short-circuiting may occur between the electrical contact end portions 72a. However, the pretreatment unit 80 includes the dry gas supply nozzle 86 so that short-circuiting between the electrical contact end portions 72a can be prevented. In cases such as a case where a wet contact is adopted in the substrate holder 60 and a case where the plating apparatus 1 does not require the substrate holder 60, the pretreatment unit 80 may not include the dry gas supply nozzle 86. In this embodiment, a wet contact is the opposite of a so-called dry contact where a space, where a power supply member is disposed, is sealed so as to prevent a direct contact between a plating solution and the power supply member. The wet contact means a contact which allows the power supply member, which is brought into contact with a peripheral edge portion of the substrate, to be brought into contact with a plating solution.

It is desirable that the dry gas supply nozzle 86 blow an inert gas onto the peripheral edge portion of the substrate W from the inner side toward the outer side of the substrate W. For example, a discharge portion of a nozzle 86a of the dry gas supply nozzle 86 can be directed in the direction from the inner side toward the outer side of the substrate W. With such a configuration, the pretreatment solution adhering to the peripheral edge portion of the substrate W can be blown off to the outside of the substrate W in the radial direction so that a speed of drying the substrate W can be increased.

The rotary cup 82 is a casing which surrounds the periphery of the adsorption plate 81 and the substrate W. An upper portion of the rotary cup 82 is opened so as to allow irradiation of ultraviolet rays, supply of a pretreatment solution and supply of an inert gas. The rotary cup 82 is configured to receive the pretreatment solution blown off due to rotation of the substrate W and blowing of an inert gas. The rotary cup 82 includes a drain portion 83 at a bottom portion thereof so that the pretreatment solution received by the rotary cup 82 is discharged.

As shown in FIG. 5B, the ultraviolet irradiation device 84, the pretreatment solution supply nozzle 85 and the dry gas supply nozzle 86 are respectively configured to be movable between a retracted position which is retracted from the adsorption plate 81 (the position indicated by a broken line in the drawing) and a treatment position which is positioned above the adsorption plate 81 (the position indicated by a solid line in the drawing). When the substrate W is placed on the adsorption plate 81, the ultraviolet irradiation device 84, the pretreatment solution supply nozzle 85 and the dry gas supply nozzle 86 are moved to the retracted position. In such a state, the adsorption surface of the adsorption plate 81 are moved to the position higher than the upper end portion of the rotary cup 82, and the substrate W is placed on the adsorption plate 81. The adsorption plate 81 holding the substrate W is lowered and, thereafter, corresponding to treatment to be performed, any one of the ultraviolet irradiation device 84, the pretreatment solution supply nozzle 85 or the dry gas supply nozzle 86 is moved to the treatment position.

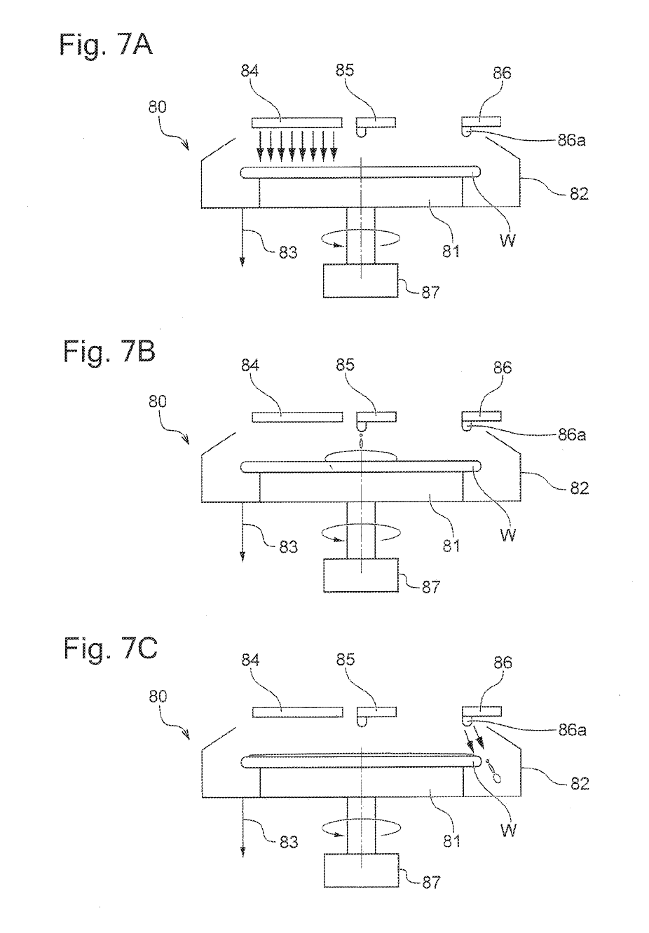

Next, the pretreatment performed in the pretreatment unit 80 is specifically described. FIG. 6 is a flowchart showing the pretreatment which is performed on the substrate W in the pretreatment unit 80. In other words, FIG. 6 is a flowchart describing step S402 shown in FIG. 4 in detail. FIG. 7A to FIG. 7C are schematic side cross-sectional views showing the pretreatment unit 80 performing the pretreatment on the substrate W. To be more specific, FIG. 7A shows the pretreatment unit 80 irradiating ultraviolet rays to the substrate W. FIG. 7B shows the pretreatment unit 80 supplying the pretreatment solution to the substrate W. FIG. 7C shows the pretreatment unit 80 blowing a dry gas onto the substrate W. Operations of the adsorption plate 81, the ultraviolet irradiation device 84, the pretreatment solution supply nozzle 85, the dry gas supply nozzle 86 and the motor 87 of the pretreatment unit 80 shown in FIG. 5A and FIG. 5B are controlled by the control part 45 shown in FIG. 1. In such a manner, a flow of the pretreatment shown in FIG. 6 is performed.

In performing the pretreatment on the substrate W in the pretreatment unit 80, firstly, the substrate W is held by the adsorption plate 81 (step S601). At this stage of the operation, a front surface of the substrate W faces upward so as to opposedly face the ultraviolet irradiation device 84. Subsequently, as shown in FIG. 7A, while the motor 87 causes the adsorption plate 81 and the substrate W to rotate, the ultraviolet irradiation device 84 irradiates ultraviolet rays to the front surface of the substrate W (step S602). With such operations, ultraviolet rays are irradiated to the entire front surface of the substrate W so that a surface to be plated is modified. To be more specific, at this stage of the operation, active oxygen is generated from a small amount of ozone present in the atmosphere by the action of ultraviolet rays. The active oxygen causes organic substances on the front surface of the substrate W to be decomposed into volatile substances. Further, by the action of the active oxygen and ultraviolet rays, a chemical bond on the resist surface is cut so that active oxygen is bonded to molecules on the resist surface. With such bonding, a functional group having high hydrophilicity is imparted to the resist surface. That is, by irradiating ultraviolet rays to the front surface of the substrate W, hydrophobic substances on the front surface of the substrate W are removed and cleaned so that the front surface of the substrate W is modified to have hydrophilicity. This treatment is referred to as hydrophilizing treatment in this embodiment.

In step S602, an ultraviolet irradiation time to the front surface of the substrate W is preferably set to from approximately ten seconds to approximately three minutes, for example. The irradiation time may be suitably determined corresponding to an elapsed time from the ashing treatment performed on the substrate W before the substrate W is carried into the plating apparatus 1. When an ultraviolet irradiation time becomes shorter than ten seconds, there is a possibility that hydrophobic organic substances adhering to the front surface of the substrate W cannot be sufficiently removed. On the other hand, when an ultraviolet irradiation time exceeds three minutes, there is a possibility that a resist on the front surface of the substrate W is ashed. As shown in FIG. 3, in a state where the substrate W is held by the substrate holder 60, the front surface of the substrate W is divided into a surface to be plated W1 to which plating is to be applied and a surface which is sealed by the substrate holder 60 and with which the electrical contacts 72 are brought into contact (sealed region W2). A resist is not formed on the sealed region W2 so that there is no possibility that a resist is ashed. A surface of a portion of the substrate, to which the electrical contacts 72 of the substrate holder 60 are brought into contact, may be further modified by setting an ultraviolet irradiation time to the sealed region W2 longer than an ultraviolet irradiation time to the surface to be plated W1. Ultraviolet rays different in wavelength and/or optical intensity may be irradiated to the surface to be plated W1 and the sealed region W2.

In step S602, it is preferable that the control part 45 (see FIG. 1) control the motor 87 and the ultraviolet irradiation device 84 so as to start irradiation of ultraviolet rays to the surface to be plated of the substrate W after rotation of the adsorption plate 81 starts. When the irradiation of ultraviolet rays starts in a state where the rotation of the substrate W is stopped, during the period where the rotation of the substrate W is stopped, ultraviolet rays are irradiated to a portion of the substrate W so that ultraviolet rays are irradiated to such a portion of the substrate W for a longer time compared to other portions of the substrate W. Accordingly, there is a possibility that an ultraviolet irradiation amount becomes non-uniform in the plane of the substrate W. On the other hand, according to this embodiment, the irradiation of ultraviolet rays starts after the rotation of the substrate W starts and hence, an ultraviolet irradiation amount can be made more uniform in the plane of the substrate W.

After the hydrophilizing treatment performed in step S602 is finished, as shown in FIG. 7B, the pretreatment solution supply nozzle 85 sprays or drips the pretreatment solution (pre-wet water) to an area in the vicinity of the center of the hydrophilized surface to be plated of the substrate W (step S603). At this stage of the operation, the control part 45 (see FIG. 1) controls the ultraviolet irradiation device 84, the pretreatment solution supply nozzle 85 and the motor 87 so as to supply the pretreatment solution to the surface to be plated of the substrate W in a state where the irradiation of ultraviolet rays and the rotation of the adsorption plate 81 are stopped. When the ultraviolet irradiation device 84 has a size which can irradiate ultraviolet rays to the entire front surface of the substrate W, the supply of the pretreatment solution and the irradiation of ultraviolet rays may be simultaneously performed without stopping the irradiation of ultraviolet rays.

The control part 45 may control the pretreatment solution supply nozzle 85 and the motor 87 so as to supply, subsequent to the hydrophilizing treatment, the pretreatment solution to the front surface of the substrate W in a state where the adsorption plate 81 is being rotated. In this case, it is preferable that a rotational speed of the adsorption plate 81 be increased compared to a rotational speed of the adsorption plate 81 in step S602. By increasing a rotational speed of the adsorption plate 81, a speed of diffusion of the pretreatment solution can be increased. In this case, the ultraviolet irradiation device 84 may stop the irradiation of ultraviolet rays, or may irradiate ultraviolet rays simultaneously with the supply of the pretreatment solution.

In step S603, the substrate W is rotated at a predetermined rotational speed so that a centrifugal force is generated against surface tension of the pretreatment solution supplied onto the substrate W whereby the pretreatment solution uniformly spreads toward the peripheral edge portion of the substrate W. The surface to be plated of the substrate W is hydrophilized in step S602 so that air in resist openings on the front surface of the substrate W can be easily replaced with the pretreatment solution. According to this embodiment, in the case of a substrate W having a size of twelve inch, for example, an amount of the pretreatment solution used in step S603 can be suppressed to approximately several hundred ml. Accordingly, compared to the conventional case where a substrate W is immersed in a pre-wetting bath, the amount of the pretreatment solution used can be largely reduced. To uniformly diffuse the pretreatment solution on the surface to be plated of the substrate W in step S603, parameters such as a supply amount of the pretreatment solution, a rotational speed of the substrate W and a time during which the substrate W is rotated can be suitably controlled. In step S603, it is preferable to supply the pretreatment solution after the completion of the irradiation of ultraviolet rays to the substrate W (step S602). By supplying the pretreatment solution as described above, it is possible to prevent ultraviolet rays from being absorbed by the pretreatment solution so that the substrate W can be efficiently modified in step S602.

After the pretreatment solution is supplied to the entire front surface of the substrate W, the supply of the pretreatment solution is stopped. Subsequently, as shown in FIG. 7C, in a state where the substrate W is being rotated, an inert gas (for example, nitrogen gas) is blown onto the peripheral edge portion of the substrate W from the dry gas supply nozzle 86 so as to dry the peripheral edge portion of the substrate W (step S604). At this stage of the operation, as described above, it is desirable that the dry gas supply nozzle 86 blow an inert gas onto the peripheral edge portion of the substrate W from the inner side toward the outer side of the substrate W. With such an operation, the pretreatment solution adhering to the peripheral edge portion of the substrate W is blown off to the outside in the radial direction of the substrate W so that a speed of drying the substrate W can be increased. For example, in some cases including a case where a wet contact is adopted in the substrate holder 60 and a case where it is not necessary to hold the substrate W by the substrate holder 60, step S604 is not necessarily performed. The pretreatment unit 80 includes a dry gas supply source not shown in the drawing for supplying a pressurized gas to the dry gas supply nozzle 86.

Treatments of step S403 to step S410 described with reference to FIG. 4 are performed on the substrate W on which the pretreatment is performed in step S601 to step S604. With such operations, a plating film is formed on the substrate W.

As has been described heretofore, in the plating apparatus according to this embodiment, the pretreatment unit 80 can irradiate ultraviolet rays to the substrate W (hydrophilizing treatment) and also can supply the pretreatment solution to the substrate W. Accordingly, pre-wetting treatment can be performed on the substrate W immediately after the front surface of the substrate W are cleaned and modified by irradiating ultraviolet rays to the substrate W. In other words, a time before the pre-wetting treatment is performed after the entire front surface of the substrate W is cleaned and modified can be set to an extremely short time. At the same time, a time from cleaning and modification of the substrate performed by the irradiation of ultraviolet rays to the pre-wetting treatment can be set to a fixed time for every substrate. Accordingly, hydrophilicity of the front surface of the substrate W can be enhanced, and variations in the degree of hydrophilicity between substrates can be suppressed. Further, cleaning and modification of the substrate W and pre-wetting treatment of the substrate W can be performed at the same timing at the same place (by the same device). Accordingly, a throughput of the plating apparatus 1 can be enhanced, and footprint of the plating apparatus 1 can be made small.

In the plating apparatus according to this embodiment, the pretreatment can be performed on a substrate in the pretreatment unit 80 before the substrate is held by the substrate holder 60. Conventionally, the substrate W held by the substrate holder 60 is immersed in a pre-wetting bath. In such a case, the substrate W and the substrate holder 60 are immersed into a presoak solution in the presoaking bath 28 or a plating solution in the plating bath 34 in a latter stage in a state where not only the substrate W but also the substrate holder 60 are wetted with the pretreatment solution. In this embodiment, different from the conventional technique, the substrate holder 60 is not immersed into the pretreatment solution. Accordingly, treatment is performed on the substrate W in the presoaking bath 28 or the plating bath 34 in a state where the substrate holder 60 is not wetted and hence, it is possible to suppress the dilution of the presoak solution or the plating solution with the pretreatment solution.

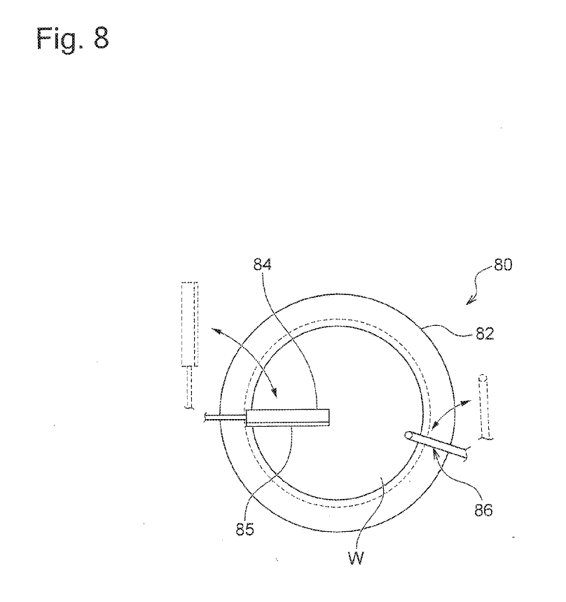

In the above-described embodiment, as shown in FIG. 5A and FIG. 5B, the ultraviolet irradiation device 84 and the pretreatment solution supply nozzle 85 are provided separately. However, the configuration is not limited to such a configuration. As shown in FIG. 8, the ultraviolet irradiation device 84 and the pretreatment solution supply nozzle 85 may be formed as an integral body. In this case, the ultraviolet irradiation device 84 and the pretreatment solution supply nozzle 85 can use the same drive source for moving the ultraviolet irradiation device 84 and the pretreatment solution supply nozzle 85 between a retracted position and a treatment position.

Although the embodiment of the present invention has been described heretofore, the above-mentioned embodiment of the present invention is provided for facilitating the understanding of the present invention, and does not limit the present invention. As a matter of course, various modifications and variations are conceivable without departing from the gist of the present invention and, at the same time, the present invention includes a technique equivalent to the present invention. Within a range where at least a portion of the above-mentioned problem can be solved or a range where at least a portion of the above-mentioned advantageous effects can be acquired, respective constitutional elements described in WHAT IS CLAIMED IS and the specification may be desirably combined or omitted.

For example, the following technique can be considered. That is, in a series of treatment steps shown in FIG. 6, after modification treatment in step S602 is performed, a surfactant is sprayed onto a rotating substrate W using a nozzle not shown in the drawing from above the substrate W so as to cover a portion of the substrate W by the surfactant. With such an operation, a region of a seed layer, which is covered by the surfactant, and a region of the seed layer, which is not covered by the surfactant, are formed on the substrate W. By covering a portion of the substrate W by such a surfactant, when electrolytic plating treatment is performed on the substrate W, a speed of plating the region of the seed layer which is not covered by the surfactant can be relatively increased. On the other hand, a speed of plating the region of the seed layer which is covered by the surfactant can be relatively reduced. Accordingly, it is possible to prevent formation of voids in recessed portions of the substrate W and hence, electrolytic plating, which is bottom up plating, can be easily performed also on a substrate W having a trench structure or a via structure with high aspect ratio. The surfactant which covers the substrate W is dissolved in the plating solution by immersing the substrate W into the plating solution for a certain period of time.

Hereinafter, several aspects disclosed in this specification are described.

According to a first aspect, there is provided the plating apparatus for performing plating treatment on a substrate. The plating apparatus includes: the pretreatment unit configured to cause a surface of the substrate to be brought into contact with a pretreatment solution; and the plating bath in which the plating treatment is performed on the substrate having the surface which is brought into contact with the pretreatment solution. The pretreatment unit includes: the holding table configured to hold the substrate with the surface of the substrate facing upward; the motor configured to rotate the holding table; the hydrophilizing treatment portion configured to irradiate ultraviolet rays to the surface; and the pretreatment solution supply portion configured to supply the pretreatment solution to the surface which is hydrophilized by the hydrophilizing treatment portion.

According to the first aspect, the pretreatment unit can irradiate ultraviolet rays to the substrate (hydrophilizing treatment) and also can supply the pretreatment solution. Accordingly, pre-wetting treatment can be performed on the substrate immediately after the front surface of the substrate are cleaned and modified by irradiating ultraviolet rays. In other words, a time before the pre-wetting treatment is performed after the entire front surface of the substrate is cleaned and modified can be set to an extremely short time. At the same time, a time from cleaning and modification of the substrate performed by the irradiation of ultraviolet rays to the pre-wetting treatment can be set to a fixed time for every substrate. Accordingly, hydrophilicity of the front surface of the substrate can be enhanced, and variations in the degree of hydrophilicity between substrates can be suppressed. Further, cleaning and modification of the substrate and the pre-wetting treatment on the substrate can be performed at the same timing at the same place (by the same device). Accordingly, a throughput of the plating apparatus can be enhanced, and footprint of the plating apparatus can be made small.

Further, according to the first aspect, the holding table holds the substrate so that the substrate can be rotated. Accordingly, it is possible to irradiate ultraviolet rays from the hydrophilizing treatment portion while the substrate is being rotated. For this reason, even when ultraviolet rays are locally irradiated to the substrate, for example, due to the rotation of the substrate, ultraviolet rays can be irradiated to the entire substrate. With such a configuration, compared to the case where the hydrophilizing treatment portion irradiates ultraviolet rays to the entire substrate, a size of the hydrophilizing treatment portion can be reduced. Further, when the pretreatment solution supply portion supplies a treatment solution to the hydrophilized substrate, the holding table holding the substrate can be rotated at a predetermined rotational speed. Accordingly, a centrifugal force is generated against surface tension of the pretreatment solution supplied onto the substrate so that the pretreatment solution uniformly spreads toward the peripheral edge portion of the substrate. The front surface of the substrate is hydrophilized so that air in resist openings on the front surface of the substrate can be easily replaced with the pretreatment solution. In the first aspect, with the rotation of the substrate, it is possible to spread the pretreatment solution from the center of the substrate toward the peripheral edge portion of the substrate. For this reason, in the case of a substrate having a size of twelve inch, an amount of a pretreatment solution used can be suppressed to approximately several hundred ml. Accordingly, compared to the conventional case where a substrate is immersed in a pre-wetting bath, an amount of the pretreatment solution used can be largely reduced.

According to a second aspect, the plating apparatus of the first aspect includes the gas supply portion configured to blow a gas onto a peripheral edge portion of the substrate.

According to the second aspect, a gas is blown onto the peripheral edge portion of the substrate by the gas supply portion while the substrate is being rotated so that the pretreatment solution adhering to the peripheral edge portion of the substrate can be removed or dried. In applying plating to the substrate, electrical contact end portions of the substrate holder are brought into contact with the peripheral edge portion of the substrate so that a power is supplied to the seed layer on the front surface of the substrate. At this stage of the operation, if the peripheral edge portion of the substrate is wetted with the pretreatment solution, there is a possibility that short-circuiting occurs between the electrical contact end portions. However, the pretreatment unit includes the gas supply portion so that short-circuiting between the electrical contact end portions can be prevented.

According to a third aspect, in the plating apparatus of the second aspect, the gas supply portion is configured to blow a gas onto the substrate from the inner side toward the outer side of the substrate.

According to the third aspect, the pretreatment solution adhering to the peripheral edge portion of the substrate is blown off to the outside in the radial direction of the substrate so that a speed of drying the substrate can be increased.

According to a fourth aspect, the plating apparatus of any one of the first to third aspects includes the control part configured to control the pretreatment solution supply portion, the hydrophilizing treatment portion, and the motor. According to the fourth aspect, the control part can suitably control respective parts of the pretreatment unit.

According to a fifth aspect, in the plating apparatus of the fourth aspect, the control part controls the motor and the hydrophilizing treatment portion so as to start irradiation of ultraviolet rays to the surface after rotation of the holding table starts.

Assume a case where the hydrophilizing treatment portion is configured to locally irradiate ultraviolet rays to the substrate. In such a case, when the irradiation of ultraviolet rays starts in a state where the rotation of the substrate is stopped, during the period where the rotation of the substrate is stopped, ultraviolet rays are irradiated to a portion of the substrate so that ultraviolet rays are irradiated to such a portion of the substrate for a longer time compared to other portions of the substrate. Accordingly, there is a possibility that an ultraviolet irradiation amount becomes non-uniform in the plane of the substrate. According to the fifth aspect, the irradiation of ultraviolet rays starts after the rotation of the substrate starts and hence, an ultraviolet irradiation amount can be made more uniform in the plane of the substrate.

According to a sixth aspect, in the plating apparatus of the fourth or fifth aspect, the control part controls the pretreatment solution supply portion and the motor so as to supply the pretreatment solution to the hydrophilized surface in a state where rotation of the holding table is stopped.

According to a seventh aspect, in the plating apparatus of the fourth or fifth aspect, the control part controls the pretreatment solution supply portion and the motor so as to supply the pretreatment solution to the hydrophilized surface in a state where the holding table is being rotated.

According to an eighth aspect, in the plating apparatus of the seventh aspect, the control part controls the pretreatment solution supply portion and the motor so as to supply the pretreatment solution to the hydrophilized surface in a state where a rotational speed of the holding table is increased compared to a rotational speed of the holding table at the time of irradiating the ultraviolet rays. According to the eighth aspect, a rotational speed of the holding table is increased compared to a rotational speed of the holding table at the time of irradiating ultraviolet rays and hence, a speed of diffusion of the pretreatment solution can be increased.

According to a ninth aspect, in the plating apparatus of any one of the first to eighth aspects, the plating bath is configured to perform the plating treatment on the substrate in a state where the substrate holder holds the substrate having the surface supplied with the pretreatment solution.

According to the ninth aspect, the substrate holder can hold the substrate on which the pretreatment is performed by the pretreatment unit. Conventionally, a substrate held by a substrate holder is immersed in a pre-wetting bath. In such a case, the substrate and the substrate holder are immersed into a plating solution in a plating bath in a latter stage in a state where not only the substrate but also the substrate holder are wetted with the pretreatment solution. In the ninth aspect, different from the conventional technique, the substrate holder is not immersed into the pretreatment solution. Accordingly, treatment is performed on the substrate in the plating bath in a state where the substrate holder is not wetted and hence, it is possible to suppress the dilution of the plating solution with the pretreatment solution.

According to a tenth aspect, there is provided the plating method. The plating method includes: a step of placing the substrate on the holding table; a step of performing the hydrophilizing treatment by irradiating ultraviolet rays to the surface of the substrate placed on the holding table; a step of supplying the pretreatment solution to the surface of the substrate on which the hydrophilizing treatment is performed; a step of rotating the holding table holding the substrate having the surface supplied with the pretreatment solution; and a plating step of performing the plating treatment on the substrate having the surface supplied with the pretreatment solution.

According to the tenth aspect, the holding table holds the substrate so that the substrate can be rotated. Accordingly, it is possible to irradiate ultraviolet rays while the substrate is being rotated. For this reason, even when ultraviolet rays are locally irradiated to the substrate, for example, due to the rotation of the substrate, ultraviolet rays can be irradiated to the entire substrate. With such a configuration, compared to the case where ultraviolet rays are irradiated to the entire substrate, a size of the ultraviolet irradiation device can be reduced. Further, when a treatment solution is supplied to the hydrophilized substrate, the holding table holding the substrate can be rotated at a predetermined rotational speed. Accordingly, a centrifugal force is generated against surface tension of the pretreatment solution supplied onto the substrate so that the pretreatment solution uniformly spreads toward the peripheral edge portion of the substrate. The front surface of the substrate is hydrophilized so that air in resist openings on the front surface of the substrate can be easily replaced with the pretreatment solution. In the tenth aspect, with the rotation of the substrate, it is possible to spread the pretreatment solution from the center of the substrate toward the peripheral edge portion of the substrate. For this reason, in the case of a substrate having a size of twelve inch, an amount of a pretreatment solution used can be suppressed to approximately several hundred ml. Accordingly, compared to the conventional case where a substrate is immersed in a pre-wetting bath, an amount of the pretreatment solution used can be largely reduced.

According to an eleventh aspect, the plating method of the tenth aspect further includes a step of blowing a gas onto the peripheral edge portion of the substrate having the surface supplied with the pretreatment solution.

According to the eleventh aspect, a gas is blown onto the peripheral edge portion of the substrate while the substrate is being rotated so that the pretreatment solution adhering to the peripheral edge portion of the substrate can be removed or dried. In applying plating to the substrate, the electrical contact end portions of the substrate holder are brought into contact with the peripheral edge portion of the substrate so that a power is supplied to the seed layer on the front surface of the substrate. At this stage of the operation, if the peripheral edge portion of the substrate is wetted with the pretreatment solution, there is a possibility that short-circuiting occurs between the electrical contact end portions. In view of the above, by blowing a gas onto the peripheral edge portion of the substrate, short-circuiting between the electrical contact end portions can be prevented.

According to a twelfth aspect, in the plating method of the eleventh aspect, the step of blowing the gas includes a step of blowing the gas onto the substrate from the inner side toward the outer side of the substrate.

According to the twelfth aspect, the pretreatment solution adhering to the peripheral edge portion of the substrate is blown off to the outside in the radial direction of the substrate so that a speed of drying the substrate can be increased.

According to a thirteenth aspect, in the plating method of any one of the tenth to twelfth aspects, the step of performing the hydrophilizing treatment includes a step of starting irradiation of ultraviolet rays to the surface after rotation of the holding table starts.

Assume a case where ultraviolet rays are locally irradiated to the substrate. In such a case, when the irradiation of ultraviolet rays starts in a state where the rotation of the substrate is stopped, during the period where the rotation of the substrate is stopped, ultraviolet rays are irradiated to a portion of the substrate so that ultraviolet rays are irradiated to such a portion of the substrate for a longer time compared to other portions of the substrate. Accordingly, there is a possibility that an ultraviolet irradiation amount becomes non-uniform in the plane of the substrate. According to the thirteenth aspect, the irradiation of ultraviolet rays starts after the rotation of the substrate starts and hence, an ultraviolet irradiation amount can be made more uniform in the plane of the substrate.

According to a fourteenth aspect, in the plating method of any one of the tenth to thirteenth aspect, the step of supplying the pretreatment solution includes a step of supplying the pretreatment solution to the hydrophilized surface in a state where rotation of the holding table is stopped.

According to a fifteenth aspect, in the plating method of any one of the tenth to thirteenth aspect, the step of supplying the pretreatment solution includes a step of supplying the pretreatment solution to the hydrophilized surface in a state where the holding table is being rotated.

According to a sixteenth aspect, in the plating method of the fifteenth aspect, the step of supplying the pretreatment solution includes a step of supplying the pretreatment solution to the hydrophilized surface in a state where a rotational speed of the holding table is increased compared to a rotational speed of the holding table at the time of irradiating the ultraviolet rays. According to the sixteenth aspect, a rotational speed of the holding table is increased compared to a rotational speed of the holding table at the time of irradiating ultraviolet rays and hence, a speed of diffusion of the pretreatment solution can be increased.

According to a seventeenth aspect, in the plating method of any one of the tenth to sixteenth aspects, the plating step includes: a step of holding, by the substrate holder, the substrate having the surface supplied with the pretreatment solution; and a step of performing the plating treatment on the substrate held by the substrate holder.

According to the seventeenth aspect, the substrate holder can hold the substrate to which the pretreatment solution is supplied. Conventionally, a substrate held by a substrate holder is immersed in a pre-wetting bath. In such a case, the substrate and the substrate holder are immersed into a plating solution in a plating bath in a latter stage in a state where not only the substrate but also the substrate holder are wetted with the pretreatment solution. In the seventeenth aspect, different from the conventional technique, the substrate holder is not immersed into the pretreatment solution. Accordingly, treatment is performed on the substrate in the plating bath in a state where the substrate holder is not wetted and hence, it is possible to suppress the dilution of the plating solution with the pretreatment solution.

According to an eighteenth aspect, in the plating method of any one of the tenth to seventeenth aspects, the step of performing the hydrophilizing treatment includes a step of irradiating ultraviolet rays to the substrate such that an ultraviolet irradiation time to the surface to be plated of the substrate is made different from an ultraviolet irradiation time to a sealed region of the substrate.

In a state where the substrate is held by the substrate holder, the front surface of the substrate is divided into a surface to be plated to which plating is to be applied and a surface which is sealed by the substrate holder and with which electrical contacts are brought into contact (sealed region). A resist is not formed in the sealed region so that there is no possibility that the resist is ashed. According to the eighteenth aspect, for example, by setting an ultraviolet irradiation time to the sealed region longer than an ultraviolet irradiation time to the surface to be plated, it is possible to cause the front surface of a portion of the substrate to be further modified, to which the electrical contacts of the substrate holder are brought into contact.

According to a nineteenth aspect, in the plating method of any one of the tenth to eighteenth aspects, the step of performing the hydrophilizing treatment includes a step of irradiating ultraviolet rays different in wavelength and/or optical intensity to the surface to be plated and the sealed region of the substrate.

As described above, a resist is not formed in the sealed region. For this reason, according to the nineteenth aspect, for example, by irradiating ultraviolet rays different in wavelength and/or optical intensity to the surface to be plated W1 and the sealed region W2, it is possible to irradiate ultraviolet rays suitable for causing modification of the respective regions to the respective regions.

According to a twentieth aspect, in the plating method of any one of the tenth to nineteenth aspects, the pretreatment solution is formed of any one of or any combination of DIW, dilute sulfuric acid, an aqueous solution containing an additive used in a plating solution or an aqueous solution containing chloride ions used in the plating solution. The pretreatment solution does not contain metal ions.

According to the twenty first aspect, there is provided the computer readable recording medium. A program is recorded in the recording medium, wherein upon execution of the program by a computer which controls an operation of the plating apparatus, the computer controls the plating apparatus so as to execute the plating method described in any one of tenth to twentieth aspects.

### REFERENCE SIGNS LIST

1: plating apparatus
45: control part
60: substrate holder
80: pretreatment unit
81: adsorption plate
84: ultraviolet irradiation device
85: pretreatment solution supply nozzle
86: dry gas supply nozzle
87: motor

What is claimed is:

1. A plating apparatus for performing plating treatment on a substrate, the plating apparatus comprising:
a pretreatment unit configured to cause a surface of the substrate to be brought into contact with a pretreatment solution; and
a plating bath in which the plating treatment is performed on the substrate having the surface which is brought into contact with the pretreatment solution, wherein
the pretreatment unit includes:
a holding table configured to hold the substrate with the surface of the substrate facing upward;
a motor configured to rotate the holding table;
a hydrophilizing treatment portion configured to irradiate ultraviolet rays to the surface; and
a pretreatment solution supply portion configured to supply the pretreatment solution to the surface which is hydrophilized by the hydrophilizing treatment portion.

2. The plating apparatus according to claim 1, further comprising a gas supply portion configured to blow a gas onto a peripheral edge portion of the substrate.

3. The plating apparatus according to claim 2, wherein
the gas supply portion is configured to blow a gas onto the substrate from an inner side toward an outer side of the substrate.

4. The plating apparatus according to claim 1, further comprising a control part configured to control the pretreatment solution supply portion, the hydrophilizing treatment portion, and the motor.

5. The plating apparatus according to claim 4, wherein
the control part is configured to control the motor and the hydrophilizing treatment portion so as to start irradiation of ultraviolet rays to the surface after rotation of the holding table starts.

6. The plating apparatus according to claim 4, wherein
the control part is configured to control the pretreatment solution supply portion and the motor so as to supply the pretreatment solution to the hydrophilized surface in a state where rotation of the holding table is stopped.

7. The plating apparatus according to claim 4, wherein
the control part is configured to control the pretreatment solution supply portion and the motor so as to supply the pretreatment solution to the hydrophilized surface in a state where the holding table is being rotated.

8. The plating apparatus according to claim 7, wherein
the control part is configured to control the pretreatment solution supply portion and the motor so as to supply the pretreatment solution to the hydrophilized surface in a state where a rotational speed of the holding table is increased compared to a rotational speed of the holding table at the time of irradiating the ultraviolet rays.

9. The plating apparatus according to claim 1, wherein
the plating bath is configured to perform the plating treatment on the substrate in a state where a substrate holder holds the substrate having the surface supplied with the pretreatment solution.

10. A plating method comprising:
a step of placing a substrate on a holding table;
a step of performing hydrophilizing treatment by irradiating ultraviolet rays to a surface of the substrate placed on the holding table;
a step of supplying a pretreatment solution to the surface of the substrate on which the hydrophilizing treatment is performed;
a step of rotating the holding table holding the substrate having the surface supplied with the pretreatment solution; and
a plating step of performing plating treatment on the substrate having the surface supplied with the pretreatment solution.

11. The plating method according to claim 10, further comprising
a step of blowing a gas onto a peripheral edge portion of the substrate having the surface supplied with the pretreatment solution.

12. The plating method according to claim 11, wherein
the step of blowing the gas includes a step of blowing the gas onto the substrate from an inner side toward an outer side of the substrate.

13. The plating method according to claim 10, wherein
the step of performing the hydrophilizing treatment includes a step of starting irradiation of ultraviolet rays to the surface after rotation of the holding table starts.

14. The plating method according to claim 10, wherein
the step of supplying the pretreatment solution includes a step of supplying the pretreatment solution to the hydrophilized surface in a state where rotation of the holding table is stopped.

15. The plating method according to claim 10, wherein
the step of supplying the pretreatment solution includes a step of supplying the pretreatment solution to the hydrophilized surface in a state where the holding table is being rotated.

16. The plating method according to claim 15, wherein
the step of supplying the pretreatment solution includes a step of supplying the pretreatment solution to the hydrophilized surface in a state where a rotational speed of the holding table is increased compared to a rotational speed of the holding table at the time of irradiating the ultraviolet rays.

17. The plating method according to claim 10, wherein
the plating step includes: a step of holding, by a substrate holder, the substrate having the surface supplied with the pretreatment solution; and a step of performing the plating treatment on the substrate held by the substrate holder.

18. The plating method according to claim 10, wherein
the step of performing the hydrophilizing treatment includes a step of irradiating ultraviolet rays to the substrate such that an ultraviolet irradiation time to a surface to be plated of the substrate is made different from an ultraviolet irradiation time to a sealed region of the substrate.

19. The plating method according to claim 10, wherein
the step of performing the hydrophilizing treatment includes a step of irradiating ultraviolet rays different in wavelength and/or optical intensity to a surface to be plated and a sealed region of the substrate.

20. The plating method according to claim 10, wherein
the pretreatment solution is formed of any one of or any combination of DIW, dilute sulfuric acid, an aqueous solution containing an additive used in a plating solution or an aqueous solution containing chloride ions used in the plating solution, and the pretreatment solution does not contain metal ions.

21. A computer readable recording medium in which a program is recorded, wherein upon execution of the program by a computer which is configured to control an operation of a plating apparatus, the computer controls the plating apparatus so as to execute the plating method described in claim 10.
